(19) United States
(12) Patent Application Publication
(10) Pub. No.: US 2026/0366151 A1
(43) Pub. Date: Nov. 19, 2026

(54) SUBSTRATE PROCESSING SYSTEMS AND METHODS THAT USE MOISTURE CONCENTRATION FOR CONTROLLING PURGE GAS FLOW

(71) Applicant: ASM IP Holding B.V., Almere (NL)

(72) Inventor: Wataru Kobayashi, Sagamihara-shi (JP)

(21) Appl. No.: 19/674,823

(22) Filed: May 12, 2026

Related U.S. Application Data
(60) Provisional application No. 63/805,632, filed on May 14, 2025.

(51) Int. Cl. C23C 16/44; C23C 16/52

(52) U.S. Cl. CPC C23C 16/4408; C23C 16/52

(57) ABSTRACT

Substrate processing systems and methods use information relating to the moisture content within a chamber for controlling purge gas flow within the chamber. In such systems and methods, the purge gas flow rate is changeable between a high flow rate and a low flow rate. A high purge gas flow rate is used (e.g., opening a high flow rate pressure valve and an exhaust gas pressure valve) until the moisture concentration reaches a first threshold level. Then, in at least some examples, purge gas flow is stopped (e.g., all pressure valves are closed). Thereafter, a low purge gas flow rate can be used, e.g., after a certain time period and/or whenever the moisture concentration increases above a second threshold. The low flow rate can be provided by opening a low flow purge gas pressure valve and the exhaust gas pressure valve.

### CROSS-REFERENCE TO RELATED APPLICATIONS

This application claims priority to U.S. Provisional Patent Application Ser. No. 63/805,632 filed May 14, 2025 titled SUBSTRATE PROCESSING SYSTEMS AND METHODS THAT USE MOISTURE CONCENTRATION FOR CONTROLLING PURGE GAS FLOW, the disclosure of which is hereby incorporated by reference in its entirety.

### FIELD OF THE DISCLOSURE

The present disclosure relates generally to substrate processing systems and methods. Aspects of this technology use information relating to the moisture content within a chamber for controlling purge gas flow within the chamber.

### BACKGROUND OF THE DISCLOSURE

Material layers are commonly deposited onto substrates during fabrication of semiconductor devices, such as during fabrication of integrated circuits and electronic devices. Material layer deposition generally is accomplished by supporting a substrate within a substrate processing chamber arrangement, heating the substrate to a desired deposition temperature, and flowing one or more material layer precursors through the chamber arrangement and across the substrate. As the precursor flows across the substrate, the material layer progressively develops onto the surface of the substrate, typically according to the temperature of the substrate and environmental conditions within the chamber arrangement.

Conventional semiconductor production systems and methods generally have been acceptable for their intended purpose, but there is room for improvement. Improvements that reduce equipment costs, reduce consumable usage, reduce maintenance costs, and/or reduce system down time would be welcome advances in the art.

### SUMMARY OF THE DISCLOSURE

Aspects of this technology relate to substrate processing systems and methods that use information relating to the moisture content within a chamber for controlling purge gas flow within the chamber.

In accordance with aspects of this technology, the purge gas flow rate is changeable between a high flow rate and a low flow rate. High purge gas flow rate is used (e.g., opening a high flow rate pressure valve and an exhaust gas pressure valve) until the moisture concentration within the chamber reaches a first threshold level. Then, in at least some examples, purge gas flow is stopped (e.g., all pressure valves are closed). Thereafter, a low purge gas flow rate can be used, e.g., after a certain time period and/or whenever the moisture concentration increases above a second threshold (which may be the same as or different from the first threshold). The low flow rate can be provided by opening a low flow purge gas pressure valve and the exhaust gas pressure valve.

Semiconductor or other substrate processing systems in accordance with at least some examples of this technology may include one or more of: (A) a chamber defining an interior volume through which substrates are introduced into the substrate processing system and substrates are removed from the substrate processing system; (B) a moisture concentration sensor for sensing moisture concentration in the interior volume of the chamber; (C) one or more purge gas inlet lines configured to supply purge gas to the interior volume; (D) a high flow rate purge gas supply valve connected to one of the one or more purge gas inlet lines, the high flow rate purge gas supply valve configured to change between an open configuration and a closed configuration; (E) a low flow rate purge gas supply valve connected to one of the one or more purge gas inlet lines, the low flow rate purge gas supply valve configured to change between an open configuration and a closed configuration; (F) a purge gas outlet line configured to remove purge gas from the interior volume; and/or (G) a purge gas outlet valve configured to change between an open configuration in which purge gas can flow through the purge gas outlet line and a closed configuration in which purge gas cannot flow through the purge gas outlet line.

In addition to one or more of the features described above, or as an alternative, in at least some examples of this technology, the substrate processing system may additionally comprise: a control system programmed and configured to selectively change each of the high flow rate purge gas supply valve, the low flow rate purge gas supply valve, and the purge gas outlet valve between their open configuration and their closed configuration.

In addition to one or more of the features described above, or as an alternative, in at least some examples of this technology, at system start up, the control system may be programmed and configured to: (a) place or maintain each of the high flow rate purge gas supply valve and the purge gas outlet valve in its open configuration and (b) place or maintain the low flow rate purge gas supply valve in its closed configuration such that purge gas flow through the chamber until the moisture concentration sensor senses moisture concentration in the chamber is at or below a first threshold level, at which time the control system is programmed and configured to place each of the high flow rate purge gas supply valve and the purge gas outlet valve in its closed configuration.

In addition to one or more of the features described above, or as an alternative, in at least some examples of this technology, the control system further may be programmed and configured to receive moisture concentration input data from the moisture concentration sensor after the control system has placed each of the high flow rate purge gas supply valve and the purge gas outlet valve in its closed configuration.

In addition to one or more of the features described above, or as an alternative, in at least some examples of this technology, when the moisture concentration input data indicates that the moisture concentration in the chamber has moved above a second threshold level, the control system further may be programmed and adapted to place or maintain each of the low flow rate purge gas supply valve and the purge gas outlet valve in its open configuration such that purge gas flows through the chamber at a low flow rate until the moisture concentration input data indicates that the moisture concentration in the chamber is within a predetermined concentration that is at or below a third threshold level.

In addition to one or more of the features described above, or as an alternative, in at least some examples of this technology, the substrate processing system may further comprise: a pressure sensor for sensing gas pressure within the chamber, wherein the pressure sensor sends pressure input data to the control system.

In addition to one or more of the features described above, or as an alternative, in at least some examples of this technology, the control system further may be programmed and configured to place or maintain the purge gas outlet valve in its closed configuration when the pressure input data indicates that gas pressure in the chamber has fallen below a low pressure threshold level.

In addition to one or more of the features described above, or as an alternative, in at least some examples of this technology, the substrate processing system may further comprise a low pressure system alarm, wherein the low pressure system alarm is activated when the pressure input data indicates that the gas pressure in the chamber has fallen below the low pressure threshold level.

In addition to one or more of the features described above, or as an alternative, in at least some examples of this technology, the control system further may be programmed and configured to: (a) place or maintain the high flow rate purge gas supply valve in its closed configuration, (b) place or maintain the low flow rate purge gas supply valve in its closed configuration, and (c) place or maintain the purge gas outlet valve in its open configuration when the pressure input data indicates that gas pressure in the chamber has risen above a high pressure threshold level.

In addition to one or more of the features described above, or as an alternative, in at least some examples of this technology, the substrate processing system further may comprise a high pressure system alarm, wherein the high pressure system alarm is activated when the pressure input data indicates that the gas pressure in the chamber has risen above the high pressure threshold level.

In addition to one or more of the features described above, or as an alternative, in at least some examples of this technology, the substrate processing system further may comprise a pressure sensor for sensing gas pressure within the chamber.

In addition to one or more of the features described above, or as an alternative, in at least some examples of this technology, the substrate processing system further may comprise a low pressure system alarm configured to be activated when gas pressure in the chamber has fallen below a low pressure threshold level.

In addition to one or more of the features described above, or as an alternative, in at least some examples of this technology, the substrate processing system further may comprise a high pressure system alarm configured to be activated when gas pressure in the chamber has risen above a high pressure threshold level.

In addition to one or more of the features described above, or as an alternative, in at least some examples of this technology, the chamber may comprise an extended front end module of the substrate processing system.

In addition to one or more of the features described above, or as an alternative, in at least some examples of this technology, the substrate processing system further may comprise a load-lock module operatively coupled with the extended front end module and configured to receive substrates for processing from the extended front end module and to transfer processed substrates into the extended front end module.

In addition to one or more of the features described above, or as an alternative, in at least some examples of this technology, the substrate processing system further may comprise a substrate handling robotic arm located within the chamber.

Semiconductor or other substrate processing systems in accordance with at least some examples of this technology may include one or more of: (A) a chamber defining an interior volume through which substrates are introduced into the substrate processing system and substrates are removed from the substrate processing system; (B) a moisture concentration sensor for monitoring moisture concentration in the interior volume of the chamber; and (C) a control system programmed and configured to: (i) receive moisture concentration input data from the moisture concentration sensor, the moisture concentration input data representing moisture concentration within the chamber, (ii) activate a high flow purge gas system at system start up so that purge gas flows through the chamber at a first flow rate, (iii) deactivate the high flow purge gas system when the moisture concentration input data indicates that the moisture concentration in the chamber is at or below a first threshold level, and thereafter (iv) activate a low flow purge gas system so that purge gas flows through the chamber at a second flow rate that is lower than the first flow rate when the moisture concentration input data indicates that the moisture concentration in the chamber has risen above a second threshold level, and (v) deactivate the low flow purge gas system when the moisture concentration input data indicates that the moisture concentration in the chamber is at or below a third threshold level, wherein the first threshold level, the second threshold level, and the third threshold level are the same as one another or different from one another.

In addition to one or more of the features described above, or as an alternative, in at least some examples of this technology, the substrate processing system further may comprise a pressure sensor for sensing gas pressure within the chamber, wherein the pressure sensor sends pressure input data to the control system.

In addition to one or more of the features described above, or as an alternative, in at least some examples of this technology, the control system further may be programmed and configured to place and maintain the gas pressure in the chamber within a predetermined pressure range.

In addition to one or more of the features described above, or as an alternative, in at least some examples of this technology, the control system further may be programmed and configured to close a purge gas exhaust line when the pressure input data indicates that the gas pressure in the chamber has fallen below a low pressure threshold level.

In addition to one or more of the features described above, or as an alternative, in at least some examples of this technology, wherein the control system further may be programmed and adapted to activate a low pressure system alarm when the pressure input data indicates that the gas pressure in the chamber has fallen below the low pressure threshold level.

In addition to one or more of the features described above, or as an alternative, in at least some examples of this technology, the control system further may be programmed and configured to: (a) deactivate or maintain a low flow purge gas supply and a high flow purge gas supply in a deactivated condition and (b) open or maintain in an open configuration a purge gas outlet line when the pressure input data indicates that gas pressure in the chamber has risen above a high pressure threshold level.

In addition to one or more of the features described above, or as an alternative, in at least some examples of this technology, the control system further may be programmed and adapted to activate a high pressure system alarm when the pressure input data indicates that the gas pressure in the chamber has risen above the high pressure threshold level.

In addition to one or more of the features described above, or as an alternative, in at least some examples of this technology, the chamber may comprise an extended front end module of the substrate processing system.

In addition to one or more of the features described above, or as an alternative, in at least some examples of this technology, the substrate processing system further may comprise a load-lock module operatively coupled with the extended front end module and configured to receive substrates for processing from the extended front end module and to transfer processed substrates into the extended front end module.

In addition to one or more of the features described above, or as an alternative, in at least some examples of this technology, the substrate processing system further may comprise a substrate handling robotic arm located within the chamber.

Semiconductor or other substrate processing methods in accordance with at least some examples of this technology may comprise one or more of: (A) receiving moisture concentration input data representing moisture concentration within a chamber of a substrate processing system; (B) activating a high flow purge gas system at system start up so that purge gas flows through the chamber at a first flow rate; (C) deactivating the high flow purge gas system when the moisture concentration in the chamber is at or below a first threshold level; (D) thereafter activating a low flow purge gas system so that purge gas flows through the chamber at a second flow rate that is lower than the first flow rate when the moisture concentration in the chamber has risen above a second threshold level, wherein the second threshold level is the same as or different from the first threshold level; and (E) deactivating the low flow purge gas system when the moisture concentration in the chamber is at or below a third threshold level, wherein the third threshold level is the same as or different from the second threshold level.

In addition to one or more of the features described above, or as an alternative, in at least some examples of this technology, the substrate processing method further may comprise receiving gas pressure input data representing gas pressure within the chamber.

In addition to one or more of the features described above, or as an alternative, in at least some examples of this technology, the substrate processing method further may comprise deactivating or maintaining the low flow purge gas system in a closed condition and/or closing a purge gas outlet line when the gas pressure input data indicates that the gas pressure in the chamber has fallen below a low pressure threshold level.

In addition to one or more of the features described above, or as an alternative, in at least some examples of this technology, the substrate processing method further may comprise activating a low pressure system alarm when the gas pressure in the chamber has fallen below the low pressure threshold level.

In addition to one or more of the features described above, or as an alternative, in at least some examples of this technology, the substrate processing method further may comprise deactivating or maintaining a low flow purge gas supply in a deactivated condition and opening or maintaining a purge gas outlet line in an open condition when the gas pressure in the chamber is above a high pressure threshold level.

In addition to one or more of the features described above, or as an alternative, in at least some examples of this technology, the substrate processing method further may comprise activating a high pressure system alarm when the gas pressure in the chamber is above the high pressure threshold level.

In addition to one or more of the features described above, or as an alternative, in at least some examples of this technology, the substrate processing method further may comprise placing and maintaining the gas pressure in the chamber within a predetermined pressure range.

This summary is provided to introduce a selection of concepts relating to this technology in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a cluster type substrate processing system in accordance with at least some examples of this technology;

FIG. 2 is a schematic view of a purge gas supply system in accordance with at least some examples of this technology;

FIG. 3 provides a flow diagram illustrating aspects of methods in accordance with at least some examples of this technology;

FIG. 4 provides a flow diagram illustrating aspects of methods in accordance with at least some examples of this technology; and

FIG. 5 is a schematic view of a cluster type substrate processing system in accordance with at least some examples of this technology.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION

Reference now will be made to the drawings wherein like reference numerals identify similar structural features or aspects of the subject disclosure.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers.

A substrate may be formed from semiconductor materials, including, for example, silicon (Si), silicon-germanium (SiGe), silicon oxide (SiO₂), gallium arsenide (GaAs), gallium nitride (GaN) and silicon carbide (SiC). A substrate may include a pattern or may be unpatterned, such as a so-called “blanket-type” substrate. As examples, substrates in the form of a powder may have applications for pharmaceutical manufacturing. A porous substrate may include one or more polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

In accordance with aspects of this technology, the purge gas flow rate is changeable between a high flow rate and a low flow rate. In at least some examples of this technology, the “high flow rate” may be from 5 to 15 times greater than the “low flow rate,” and in some examples, from 6 to 10 times greater. As some additional examples, the “high flow rate” in some examples of this technology may be within a range of 200 SLM to 500 SLM (and in some examples, from 250 SLM to 400 SLM or from 275 SLM to 350 SLM (e.g., at 300 SLM±5%). Additionally or alternatively, the “low flow rate” in some examples of this technology may be within a range of 20 SLM to 85 SLM (and in some examples, from 25 SLM to 75 SLM, from 30 SLM to 60 SLM, or from 30 SLM to 50 SLM). “SLM” means standard liters per minute.

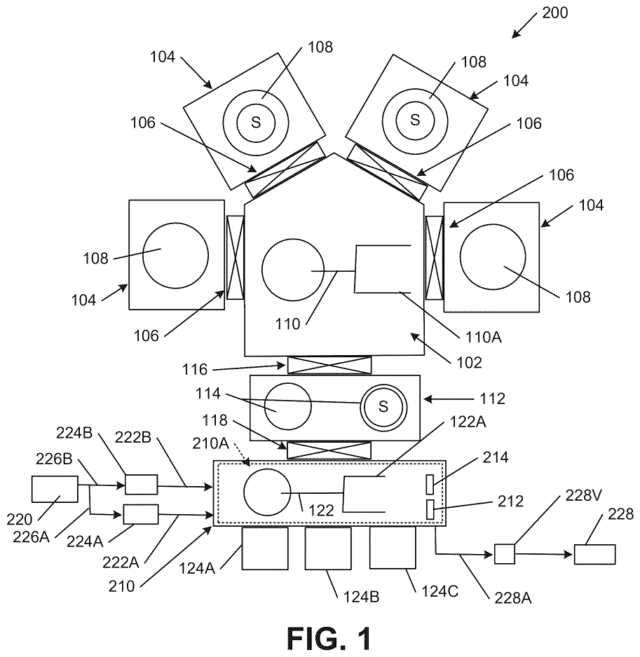

Substrate processing systems 200 in accordance with aspects of this technology may include “cluster type” systems of the type shown in FIG. 1. This substrate processing system 200 includes a substrate handling chamber 102 that operatively connects with two to four substrate processing chambers 104 via gate valves 106. Each substrate processing chamber 104 is equipped to receive a substrate S on a substrate support 108 that holds the substrate during processing (e.g., during material layer deposition as described above).

The substrate handling chamber 102 includes robotic arm 110 used to move substrates into and out of the various substrate processing chambers 104 through the gate valves 106. In use, a gate valve 106 is opened, an end effector 110A of the robotic arm 110 extends through the open gate valve 106 to insert a substrate into or remove a substrate from an interior chamber of the substrate processing chamber 104 (e.g., placing a substrate on or taking a substrate off the substrate support 108). Once the robotic arm 110 is retracted from the substrate processing chamber 104, the gate valve 106 is closed, thereby sealing the substrate processing chamber 104 from the substrate handling chamber 102. Then, other desired actions can take place in the substrate processing chamber 104 and/or the substrate handling chamber 102.

FIG. 1 further shows that this substrate processing system 200 includes a load-lock module 112. The load-lock module 112 is connected with the substrate handling chamber 102 by gate valve 116. The load-lock module 112 includes substrate holding components 114 for holding substrates on the way into the substrate handling chamber 102 for further processing and on the way out of the substrate handling chamber 102 (after processing is complete). The end effector 110A of robotic arm 110 moves through the gate valve 116 (when opened) to move substrates from the load-lock module 112 into the substrate handling chamber 102 (for layer deposition and other processing) and from the substrate handling chamber 102 into the load-lock module 112 (after processing is completed). The load-lock module 112 and gate valve 116 keep the substrates isolated from the environment of the substrate handling chamber 102 until the conditions (e.g., temperature, pressure, content of atmosphere, etc.) within the substrate handling chamber 102 are ready for the substrate(s) to be inserted.

The load-lock module 112 further is coupled with an equipment front end module 210 via another gate valve 118. The equipment front end module 210 includes a robotic arm 122. The end effector 122A of that robotic arm 122 moves through the gate valve 118 (when opened) to move substrates from the equipment front end module 210 into the load-lock module 112 (for layer deposition and other processing) and from the load-lock module 112 into the equipment front end module 210 (after processing is completed). The robotic arm 122 of the equipment front end module 210 also picks up new substrates for processing from one of the load ports 124A-124C and returns processed substrates to one of the load ports 124A-1240C, e.g., to be transported to another location for further processing.

In substrate processing systems and methods of the types described above in conjunction with FIG. 1, clean dry air, nitrogen, or other inert gas may be moved through the equipment front end module 210. Aspects of the present technology relate to the manner in which clean dry air, nitrogen, or other inert gas is moved through an equipment front end module.

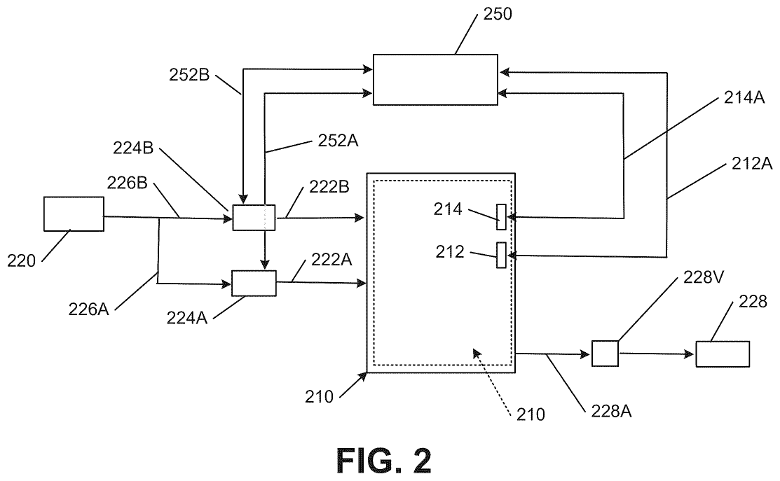

More specifically, the example substrate processing system 200 illustrated in FIG. 1 includes an equipment front end module 210 in accordance with aspects of this technology. This example equipment front end module 210 includes a chamber 210A that defines an interior volume through which substrates S are introduced into the substrate processing system 200 and substrates S are removed from the substrate processing system 200. This example chamber 210A includes:
(A) a moisture (e.g., water) concentration sensor 212 for sensing moisture concentration in the interior volume of the chamber 210A and (B) a pressure sensor 214 for sensing gas pressure within the chamber 210A. These sensors 212 and 214 and their use in accordance with aspects of this technology will be described in more detail below, e.g., in conjunction with FIGS. 2-4.

This example equipment front end module 210 further includes one or more purge gas inlet lines that supply purge gas (e.g., clean dry air, nitrogen, other inert gas, etc.) from one or more gas supplies or sources 220 to the interior volume of chamber 210A. The specifically illustrated example includes: (A) a first purge gas inlet line 222A and (B) a second purge gas inlet line 222B. The first purge gas inlet line 222A receives incoming purge gas from the source 220 (via supply line 226A) after the purge gas passes through a first pressure valve 224A. The second purge gas inlet line 222B receives incoming purge gas from the source 220 (via supply line 226B) after the purge gas passes through a second pressure valve 224B.

The first pressure valve 224A of this example (connected to supply line 226A and first purge gas inlet line 222A) comprises a high flow rate purge gas supply valve, and it is configured to change between an open configuration (in which gas flow through the valve 224A) and a closed configuration (in which gas flow through the valve 224A is stopped). The second pressure valve 224B of this example (connected to supply line 226B and second purge gas inlet line 222B), however, comprises a low flow rate purge gas supply valve. This low flow rate pressure valve 224B is configured to change between an open configuration (in which gas flow through the valve 224B) and a closed configuration (in which gas flow through the valve 224B is stopped). In at least some examples of this technology, the two pressure valves 224A and 224B provide two different (and optionally fixed) flow rates for introducing purge gas into chamber 210A. The first pressure valve 224A and the second pressure valve 224B may constitute air operation valves (valves in which opening and closing is controlled by supplying gas at a specified pressure to the valve); solenoid valves (valves in which opening and closing is controlled by supplying a specified voltage to the valve); check valves (valves in which mounting orientation controls the direction of flow and flow rate is determined based on orifice diameter, pipe conductance, and/or supply pressure, etc.); and/or the like (e.g., a relatively low cost valve (e.g., not a throttle valve) that does not require or use PID control and/or pressure feedback functions, and/or does not have self-supporting control). Suitable pressure valves 224A and 224B are commercially available, e.g., from SMC Corporation or KITZ Corporation. Pressure valves 224A and 224B need not constitute throttle valves and/or other valves with PID control and/or pressure feedback functions.

A purge gas outlet line 228A (e.g., connected to an exhaust gas vacuum pump or other appropriate exhaust equipment 228) removes purge gas from the interior volume of the chamber 210A. As further shown in the example of FIG. 1, a purge gas outlet valve 228V is provided in the purge gas outlet line 228A. The purge gas outlet valve 228V (e.g., a pressure valve) is configured to change between an open configuration (in which purge gas can flow through the purge gas outlet line 228A) and a closed configuration (in which purge gas flow through the purge gas outlet line 228A is stopped). The purge gas outlet valve 228V may constitute an air operation valve, a solenoid valve, a check valve, and/or the like (e.g., a relatively low cost valve (e.g., not a throttle valve) that does not require or use PID control and/or pressure feedback functions, and/or does not have self-supporting control, e.g., of the types described above for first pressure valve 224A and second pressure valve 224B). Suitable valves 228V are commercially available, e.g., from SMC Corporation or KITZ Corporation. Purge gas outlet valve 228V need not constitute a throttle valve and/or other valve with PID control and/or pressure feedback functions.

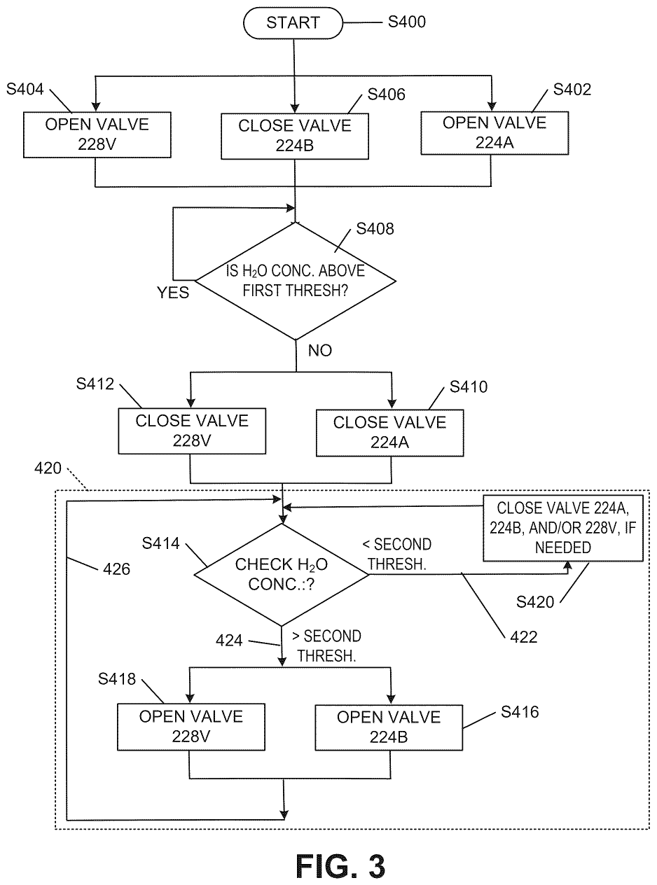

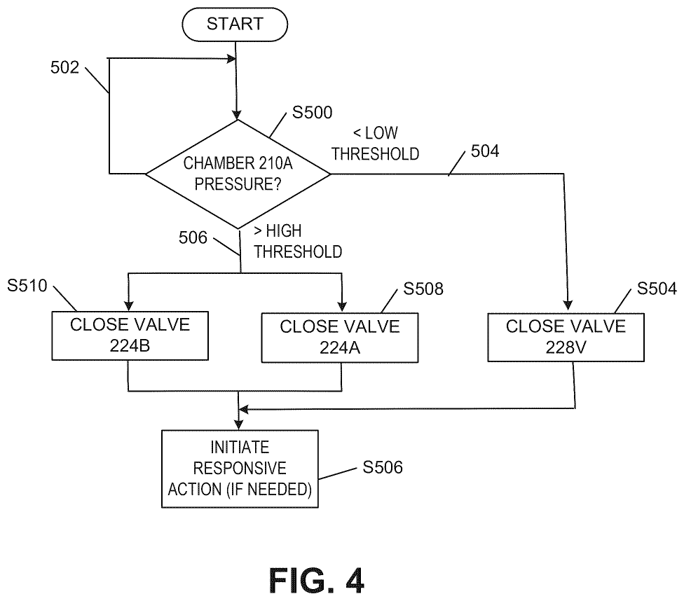

Some aspects of the present technology now will be described with additional reference to FIGS. 2-4. Where the same reference number is used in FIGS. 2-4 as used in FIG. 1 described above, the same or similar part is being referenced, and much of the duplicative description thereof may be omitted. FIG. 2 schematically illustrates features of systems and methods in accordance with aspects of this technology. FIGS. 3 and 4 provide flow diagrams illustrating example features of this technology.

In this illustrated example, both the moisture concentration sensor 212 and the pressure sensor 214 send data (e.g., via a wired or wireless connection) to a control system 250, shown by data transmission lines 212A and 214A, respectively, in FIG. 2. Electronic communications between the control system 250 and the sensors 212 and 214 may take place in any suitable manner (e.g., wired or wirelessly), using any suitable data transfer and/or communication format(s) and/or protocol(s).

The control system 250 may comprise part of the overall computer control system for operating the substrate processing system 200 and its corresponding methods, and/or it may comprise a separate computing system (optionally that receives data from and/or supplies data to the overall computer control system for operating the substrate processing system 200). The control system 250: (a) may receive input data via one or more data input ports (e.g., one or more wired or wireless connection ports), such as one or more of moisture content data from moisture concentration sensor 212, chamber 210A pressure data from pressure sensor 214, data representing the status (e.g., open or closed) of one or more of the pressure valves 224A, 224B, and/or 228V, data from a scheduler or other components of overall substrate processing system 200, etc. ; (b) may further process and/or otherwise use that data (e.g., using one or more microprocessors operating suitable data processing algorithms); (c) may generate output; (d) may transmit output data, e.g., to one or more computer controllable devices (such data to open and/or close one or more pressure valves 224A, 224B, and/or 228V); and/or (e) may save data (e.g., input data, output data, intermediately calculated or processed data, etc.) in one or more computer memory systems. The control system 250 may comprise a conventional programmable computer system that is programmed and adapted to operate and/or control components in accordance with aspects of the present technology. Operation of this example equipment front end module 210, control system 250, and substrate processing system 200 in accordance with aspects of this technology will be described in more detail below.

The control system 250 of this example is programmed and configured to transmit data to selectively change each of the high flow rate purge gas supply valve 224A, the low flow rate purge gas supply valve 224B, and the purge gas outlet valve 228V between their open configuration and their closed configuration. See data transmission lines 252A and 252B. Electronic communications between the control system 250 and the valves 224A and 224B may take place in any suitable manner (e.g., wired or wirelessly), using any suitable data transfer and/or communication format(s) and/or protocol(s).

FIG. 3 provides a flow chart schematically describing operation of control system 250 (and thus this substrate processing system 200) in accordance with at least some aspects of this technology. As shown, at substrate processing system 200 and/or control system 250 start up (S400), the control system 250 is programmed and configured to: (a) place or maintain the high flow rate purge gas supply valve 224A in its open configuration (S402), (b) place or maintain the purge gas outlet valve 228V in its open configuration (S404), and (c) place or maintain the low flow rate purge gas supply valve 224B in its closed configuration (S406). These steps may take place simultaneously (in whole or in part) or in any desired sequence. In this configuration, purge gas flows through the chamber 210A at a high flow rate and changes the content of the gas within the chamber 210A. This arrangement of the valve 224A (open), valve 224B (closed), and valve 228V (open) is maintained until the moisture concentration sensor 212 senses moisture concentration in the chamber 210A is at or below a first threshold level. This is accomplished in the example of FIG. 3 at Step S408, e.g., where the control system 250 reads the moisture concentration sensor 212 data. If the data indicates that the moisture content is above the first threshold (e.g., above 1% in some specific examples of this technology)—Answer “YES” in FIG. 3—the system 250 maintains the valve arrangement (e.g., valve 224A open, valve 224B closed, and valve 228V open), and the high flow rate purge continues.

If, at S408 the system 250 determines that the moisture content is at or below the first threshold (e.g., at or below 1% in some specific examples of this technology)—Answer “NO” in FIG. 3—the system 250 then: (a) closes the high flow rate purge gas supply valve 224A (S410) and (b) closes the purge gas outlet valve 228V (S412). At this time, in this configuration (with each of valves 224A, 224B, and 228V in its closed configuration), no purge gas is flowing through the chamber 210A. This feature reduces the amount of purge gas consumed during substrate processing methods.

Moisture concentration within the equipment front end module 210 may change over the course of time, e.g., as gate valve(s) 118 are opened and closed, as substrates move into and out of the equipment front end module 210 via load ports 124A-124C and/or load-lock module 112, etc. This example system 250 and method is programmed and configured to continue to receive and evaluate moisture content input data from the moisture concentration sensor 212, e.g., in a recurring loop 420. In this loop 420, at Step S414, the system 250 uses the moisture concentration sensor 212 data to determine if the moisture concentration in the chamber 210A has moved above a second threshold level (which may be the same as or different from the first threshold level). In some examples, the second threshold level is 1%. If the moisture content remains below the second threshold level at S414, the loop 420 returns to repeat Step S414 (see line 422). When the moisture content is below the second threshold at S414, the system 250 may confirm the status of valves 224B and 228V (and optionally valve 224A) at S420, and close any of these valves if needed at Step S420 (Step S420 may be utilized in later iterations of the loop 420, as described below).

But if at S414, the moisture concentration is found to be at or above the second threshold (line 424), this example control system 250 is programmed and adapted to: (a) place or maintain the low flow rate purge gas supply valve 224B in its open configuration (Step S416) and (b) place or maintain the purge gas outlet valve 228V in its open configuration (S418). In this manner, purge gas (e.g., clean dry air, nitrogen, or other inert gas) flows through the chamber 210A at a low flow rate (thereby further saving purge gas or reducing purge gas consumption). This process then returns to Step S414 (line 426), where the moisture concentration is again determined. The low flow rate purge gas flow will continue until the moisture concentration input data indicates that the moisture concentration in the chamber 210A is within a predetermined concentration that is at or below the second threshold level at S414 (or a different threshold level). At that time, the system 250 will close valves 224B and 228V at S420 and continue performing the evaluations in loop 420.

While not shown in the flow chart of FIG. 3, control system 250 (or other substrate processing system 200 controller) may be programmed and configured to stop the operation of the process (e.g., within the loop 420) at appropriate times and/or for appropriate reasons. For example, the process of FIG. 3 could be interrupted and/or discontinued when a manufacturer decides to stop operation of a substrate processing system 200, e.g., for maintenance, because a processing batch is complete, because of a power interrupt, or any other reason. If desired, the control system 250 (or other substrate processing system 200 controller) may be programmed and configured to run a predetermined “shutdown” and/or “interrupt” procedure with respect to the purge gas system. As one example, systems 250 and methods according to aspects of this technology may open high flow rate purge valve 224A and purge gas outlet valve 228V at least at the start of a “shutdown,” “interrupt,” or other such activities.

In at least some examples of this technology, systems 250 and methods may include a control “interrupt” process relating to pressure within the chamber 210A of the equipment front end module 210. FIG. 4 provides a flow chart schematically describing operation of control system 250 (and thus this substrate processing system 200) for a pressure interrupt process in accordance with at least some aspects of this technology. This type of pressure interrupt process may run continuously, e.g., while the chamber 210A (and/or equipment front end module 210 and/or substrate processing system 200) is in operation.

This example pressure interrupt process and method utilize data from the pressure sensor 214 that senses gas pressure in chamber 210A. At Step S500, the chamber 210A pressure is evaluated or read, e.g., to determine if it is within predetermined operating parameters (e.g., between a low pressure threshold and a high pressure threshold). If the pressure data indicates that the chamber 210A is within predetermined operating parameters, the process returns to the initial step (see process line 502), and the pressure measurement and/or pressure evaluations can be repeated.

If at S500, the chamber 210A pressure is found to be below the low pressure threshold (e.g., below 1.2 Pa—see process line 504), this example system and method will then close the purge gas outlet valve 228V (S504) (if it is open) and initiate other appropriate action, if needed (S506). Closing the purge gas outlet valve 228V will allow any incoming gas admitted into the chamber 210A to remain in the chamber 210A and thereby increase gas pressure within the chamber 210A. If necessary or desired, the other “appropriate action” activated at S506 may include opening low flow rate pressure valve 224B (if needed) to introduce additional gas into the chamber 210A (e.g., to increase pressure in the chamber 210A).

If at S500, the chamber 210A pressure is found to be above the high pressure threshold (e.g., above 80 Pa—see process line 506), this example system and method will then: (i) close the high flow rate pressure valve 224A (if it is open) at S508, (ii) close the low flow rate pressure valve 224B (if it is open) at S510, and (iii) initial other appropriate action, if needed (S506), such as opening the purge gas outlet valve 228V. Closing the high flow rate pressure valve 224A and the low flow rate pressure valve 224B with the purge gas outlet valve 228V open will allow gas to exit the chamber 210A and thereby decrease gas pressure within the chamber 210A.

The Step S506 of initiating appropriate responsive action, if needed, may take on a variety of different forms, including one or more different process steps. As one example, the responsive action may include initiating a monitoring process to again check pressure after a predetermined time period (e.g., to determine whether the actions at one or more of Steps S504, S506, S508, and/or S510 have been effective to return the chamber 210A pressure to an appropriate level within the operating parameters (e.g., between the low pressure threshold and the upper pressure threshold). Substrate processing systems 200 and/or control systems 250 and methods in accordance with at least some examples of this technology may set a predetermined time period for the responsive action(s) taken to return the pressure to a level within the operating parameters before other potential responsive—and potentially more extreme—actions are taken (e.g., activating an alarm, initiating a shut down, etc.).

Additionally or alternatively, Step S506 may include activating an alarm, such as one or more of: (i) activating a low pressure system alarm when the pressure input data (measured by pressure sensor 214) indicates that the gas pressure in the chamber 210A has fallen below the low pressure threshold level, and/or (ii) activating a high pressure system alarm when the pressure input data (measured by pressure sensor 214) indicates that the gas pressure in the chamber 210A has risen above the high pressure threshold level.

An “alarm” may take on any suitable form. As some examples, the alarm may be audio (e.g., buzzer, beeper, verbal, etc.) and/or visual (e.g., flashing light, lit up button, etc.). The alarm may be activated at a control panel for substrate processing system 200 and/or other appropriate location. Additionally or alternatively, an alarm may include sending an alert to one or more specific individuals (e.g., by text message, by email, by telephone, etc.). Additionally or alternatively, the alarm may include sending output to enter or log relevant data relating to the over-pressure and/or under-pressure condition (e.g., time, noted pressure levels, duration, etc.) in computer memory, e.g., to make this information available to the operator.

Still additionally or alternatively, the “responsive action” taken at S506 may include initiating a system shutdown, e.g., to shut down at least the equipment front end module 210 (e.g., and potentially taking other appropriate action to hold other substrates at other positions within the substrate processing system 200).

In at least some examples of this technology, substrate processing systems 200, control systems 250, and methods may have the control system 250 programmed and configured to place and maintain the gas pressure in the chamber 210A within a predetermined pressure range (e.g., between the low pressure threshold and the high pressure threshold described above in conjunction with FIG. 4). For example, when data from the pressure sensor 214 indicates that the chamber 210A pressure is approaching the high pressure threshold, the system 250 may be configured to (a) open purge gas outlet valve 228V (or increase flow rate through valve 228V) and (b) if necessary, close high flow pressure valve 224A and close (or reduce the flow rate through) low flow rate valve 224B, so that pressure reduces in the chamber 210A. Additionally or alternatively, when data from the pressure sensor 214 indicates that the chamber 210A pressure is approaching the low pressure threshold, the system 250 may be configured to (a) close the purge gas outlet valve 228V (or decrease flow rate through valve 228V), (b) if necessary, close high flow pressure valve 224A, and (c) open (or increase the flow rate through) low flow rate valve 224B, so that pressure increases in the chamber 210A.

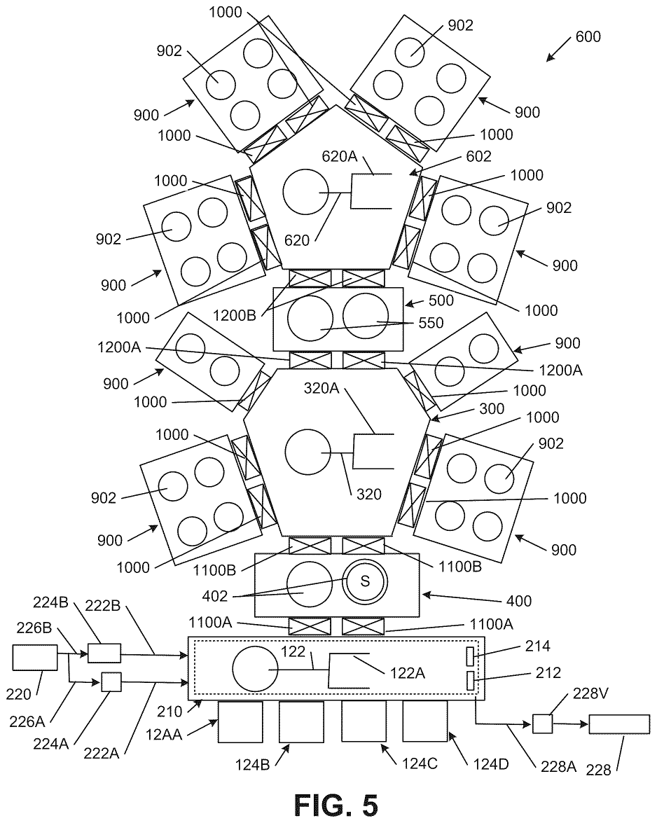

FIG. 5 schematically illustrates an overhead view of another example substrate processing system 600 (e.g., a cluster type semiconductor processing system) according to some aspects of this technology. This substrate processing system 600 has expanded substrate processing capabilities. Where the same reference number is used in FIG. 5 as used in FIGS. 1-4 described above, the same or similar part is being referenced, and much of the duplicative description may be omitted.

This example substrate processing system 600 expands substrate processing capabilities (as compared to the system 200 of FIG. 1) at least by adding an additional substrate handling chamber and one or more additional substrate processing chambers. Aspects of the present technology may be used with substrate processing systems having expanded substrate processing capabilities of the types described in U.S. Patent Appln. Publn. No. 2025/0006521 A1 filed Jun. 26, 2024, which patent application and publication are entirely incorporated herein by reference.

As shown in FIG. 5, this example substrate processing system 600 includes: (a) a first substrate handling chamber 300 (an “inboard” substrate handling chamber) including a first robotic arm 320 having an end effector 320A; (b) a first load-lock module 400 (an “inboard” load-lock module) connected at one edge or facet of the first substrate handling chamber 300; (c) a second load-lock module 500 (an “outboard” load-lock module) connected at the opposite edge or facet of the first substrate handling chamber 300; and (d) a second substrate handling chamber 602 (an “outboard” substrate handling chamber) including a second robotic arm 620 having an end effector 620A. The second load-lock module 500 extends between and connects the first substrate handling chamber 300 and the second substrate handling chamber 602.

The first load-lock module 400 of this example also is connected with an equipment front end module 210 (e.g., of the types described above in conjunction with FIGS. 1-4). This front end module 210 includes a third robotic arm 122 having an end effector 122A. The equipment front end module 210 includes the purge gas source 220 and associated hardware and control system 250 for providing an inert gas atmosphere within the equipment front end module 210. As described above, the equipment front end module 210 receives new substrates for processing into the substrate processing system 600 and discharges processed substrates from the substrate processing system 600 via one or more load ports 124A-124D (moving the substrates between the load port(s) 124A-124D and the first load-lock module 400 using the robotic arm 122). While four load ports 124A-124D are shown in the example of FIG. 5, more or fewer load ports may be provided in other specific examples of this technology.

The equipment front end module 210 illustrated in the example of FIG. 5 may have any of the structures, components, parts, and/or features of the front end modules 210 described above in conjunction with FIGS. 1-4, including any of the alternatives, variations, and/or options described above. Additionally or alternatively, the equipment front end module 210 illustrated in the example of FIG. 5 may function in any of the manners described above in conjunction with FIGS. 1-4, including any of the alternatives, variations, and/or options described above for those functions.

Each of the first substrate handling chamber 300 and the second substrate handling chamber 602 is connected with multiple substrate processing chambers 900. Substrates S are transferred into the substrate processing chambers 900 where one or more layers of material are deposited onto a surface of the substrate and/or other desired substrate processing takes place. FIG. 5 shows several substrate processing chambers 900 including four substrate supports 902 onto which substrates can be placed during processing. More or fewer substrates supports 902 may be provided in the substrate processing chambers 900 (e.g., with two of the substrate processing chambers 900 connected to inboard substrate handling chamber 300 having two substrate supports 902). Each of the substrate processing chambers 900 may have the same structures or one or more of the substrate processing chambers 900 may have a different structure from other substrate processing chambers 900 present.

Each of the first substrate handling chamber 300 and the second substrate handling chamber 602 is connected with its respective substrate processing chambers 900 via one or more gate valves 1000. While one or two gate valves 1000 are shown connecting substrate handling chambers 300, 602 with each of their respective substrate processing chambers 900, more or fewer gate valves 1000 may be provided with each substrate processing chamber 900, in other examples of this technology. When closed, the gate valves 1000 sealingly separate the substrate handling chambers 300, 602 from their respective substrate processing chambers 900 (so that independent atmospheric conditions may be maintained in each chamber). When open, the gate valves 1000 provide an opening (e.g., a substrate transfer slot) through which the end effector 320A, 620A of a robotic arm 320, 620 can extend to move substrates into and out of the substrate processing chamber 900. Each of gate valves 1000 may have the same structures or one or more of the gate valves 1000 may have a different structure from other gate valves 1000 present.

One face of the first load-lock module 400 connects with the equipment front end module 210 by one or more gate valves 1100A (two shown in FIG. 5), and the opposite face of the first load-lock module 400 connects with the first substrate handling chamber 300 by one or more gate valves 1100B (two shown in FIG. 5). The first load-lock module 400 further includes one or more substrate supports 402 (e.g., “setplates,” two shown in FIG. 5) for holding substrates while they wait to be moved into the equipment front end module 210 or the first substrate handling chamber 300. When closed, the gate valves 1100A, 1100B sealingly separate the first load-lock module 400 from the equipment front end module 210 and the substrate handling chamber 300 (so that independent atmospheric conditions may be maintained in each chamber). When open, the gate valves 1100A provide an opening (e.g., a substrate transfer slot) through which the end effector 122A of robotic arm 122 can extend to move substrates into and out of the equipment front end module 210. When open, the gate valves 1100B provide an opening (e.g., a substrate transfer slot) through which the end effector 320A of robotic arm 320 can extend to move substrates into and out of the substrate handling chamber 300. Each of gate valves 1100A, 1100B may have the same structure or one or more of the gate valves 1100A, 1100B may have a different structure from other gate valves 1100A, 1100B, 1000 present.

In the substrate processing system 600 of FIG. 5, one face of the second load-lock module 500 connects with the first substrate handling chamber 300 by one or more gate valves 1200A (two shown in FIG. 5), and the opposite face of the second load-lock module 500 connects with the second substrate handling chamber 602 by one or more gate valves 1200B (two shown in FIG. 5). The second load-lock module 500 further includes one or more substrate supports 550 (e.g., “setplates,” two shown in FIG. 5) for holding substrates while they wait to be moved between the two substrate handling chambers 300, 602. When closed, the gate valves 1200A, 1200B sealingly separate the second load-lock module 500 from the two substrate handling chambers 300, 602 (so that independent atmospheric conditions may be maintained in each chamber). When open, the gate valves 1200A provide an opening (e.g., a substrate transfer slot) through which the end effector 320A of robotic arm 320 can extend to move substrates into and out of the first substrate handling chamber 300. When open, the gate valves 1200B provide an opening (e.g., a substrate transfer slot) through which the end effector 620A of robotic arm 620 can extend to move substrates into and out of the second substrate handling chamber 602. Each of gate valves 1200A, 1200B may have the same structure or one or more of the gate valves 1200A, 1200B may have a different structure from other gate valves 1200A, 1200B present. Gate valves 1200A and/or 1200B also may have the same or different structures from gate valves 1100A and/or 1100B and/or from gate valves 1000.

The first lock-load module 400 may have the same structure as the second load-lock module 500 and/or the first and second load-lock modules 400, 500 may be interchangeable (e.g., so that load-lock modules 400, 500 can switch positions in the substrate processing system 600 and/or so that load-lock modules 400, 500 have a modular structure). In other examples, the first lock-load module 400 and the second load-lock module 500 may have different structures and/or may not be interchangeable (e.g., so that load-lock modules 400, 500 cannot switch positions in the substrate processing system 600). Either or both load-lock modules 400, 500 may be multi-station cooling capable and/or path through types.

Aspects of this technology may provide various advantages and advantageous features. For example, as noted above, the present technology can utilize relatively inexpensive and easily controllable pressure valves and do not require use of throttle valves and/or mass flow controllers in an equipment front end module. Thus, the present technology may provide some cost advantages, time savings, and less equipment downtime (e.g., as compared to using pressure control valves (e.g., throttle valves), using mass flow controllers, having to maintain these relatively expensive types of equipment, and/or having to repair or replace these relatively expensive parts).

Additionally or alternatively, as described above, at some times during substrate processing, (i) the volume of gas moving through the equipment front end module 210 can be reduced (e.g., when the low flow rate valve 224B is being used) and/or (ii) stopped (e.g., when pressure is within a desired range). These features can result in reduced consumption of clean dry air, nitrogen, and/or other inert purge gas. Thus, the present technology may provide cost advantages in this manner.

The above description and the accompanying drawings show the purge flow control system features in accordance with this technology used in an equipment front end module 210 of substrate processing systems 200, 600. Additionally or alternatively, aspects of this technology, however, may be used for other components (e.g., other chambers) of substrate processing systems (e.g., 200 and/or 600), such as substrate handling chambers, load-lock modules, etc. Additionally or alternatively, aspects of this technology also may be used in environments and/or systems other than substrate processing systems. Thus, at least some examples of the present technology are not limited to equipment front end modules.

Additionally or alternatively, in accordance with at least some aspects of this technology, the pressure valves 224A and 224B are located on the purge gas supply side of the equipment front end module 210, not the exhaust side. Thus, the substrate processing systems 200, 600 do not experience pressure fluctuations due to pressure fluctuations in the manufacturer's facility.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, and/or method described herein. In addition, any combination of two or more such features, systems, articles, materials, and/or methods, if such features, systems, articles, materials, and/or methods are not mutually inconsistent, is included within the scope of the present invention.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

In the claims, as well as in the specification above, all transitional phrases such as “comprising,” “including,” “carrying,” “having,” “containing,” “involving,” “holding,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

The headings provided herein, if any, are for convenience only and do not necessarily affect the scope or meaning of the devices and methods disclosed herein.

1. A substrate processing system, comprising:
a chamber defining an interior volume through which substrates are introduced into the substrate processing system and substrates are removed from the substrate processing system;
a moisture concentration sensor for sensing moisture concentration in the interior volume of the chamber;
one or more purge gas inlet lines configured to supply purge gas to the interior volume;
a high flow rate purge gas supply valve connected to one of the one or more purge gas inlet lines, the high flow rate purge gas supply valve configured to change between an open configuration and a closed configuration;
a low flow rate purge gas supply valve connected to one of the one or more purge gas inlet lines, the low flow rate purge gas supply valve configured to change between an open configuration and a closed configuration;
a purge gas outlet line configured to remove purge gas from the interior volume; and
a purge gas outlet valve configured to change between an open configuration in which purge gas can flow through the purge gas outlet line and a closed configuration in which purge gas cannot flow through the purge gas outlet line.

2. The substrate processing system according to claim 1, further comprising: a control system programmed and configured to selectively change each of the high flow rate purge gas supply valve, the low flow rate purge gas supply valve, and the purge gas outlet valve between their open configuration and their closed configuration.

3. The substrate processing system according to claim 2, wherein, at system start up, the control system is programmed and configured to: (a) place or maintain each of the high flow rate purge gas supply valve and the purge gas outlet valve in its open configuration and (b) place or maintain the low flow rate purge gas supply valve in its closed configuration such that purge gas flow through the chamber until the moisture concentration sensor senses moisture concentration in the chamber is at or below a first threshold level, at which time the control system is programmed and configured to place each of the high flow rate purge gas supply valve and the purge gas outlet valve in its closed configuration.

4. The substrate processing system according to claim 3, wherein the control system further is programmed and configured to receive moisture concentration input data from the moisture concentration sensor after the control system has placed each of the high flow rate purge gas supply valve and the purge gas outlet valve in its closed configuration.

5. The substrate processing system according to claim 4, wherein when the moisture concentration input data indicates that the moisture concentration in the chamber has moved above a second threshold level, the control system further is programmed and adapted to place or maintain each of the low flow rate purge gas supply valve and the purge gas outlet valve in its open configuration such that purge gas flows through the chamber at a low flow rate until the moisture concentration input data indicates that the moisture concentration in the chamber is within a predetermined concentration that is at or below a third threshold level.

6. The substrate processing system according to claim 2, further comprising: a pressure sensor for sensing gas pressure within the chamber, wherein the pressure sensor sends pressure input data to the control system.

7. The substrate processing system according to claim 6, wherein the control system further is programmed and configured to place or maintain the purge gas outlet valve in its closed configuration when the pressure input data indicates that gas pressure in the chamber has fallen below a low pressure threshold level.

8. The substrate processing system according to claim 7, further comprising a low pressure system alarm, wherein the low pressure system alarm is activated when the pressure input data indicates that the gas pressure in the chamber has fallen below the low pressure threshold level.

9. The substrate processing system according to claim 6, wherein the control system further is programmed and configured to: (a) place or maintain the high flow rate purge gas supply valve in its closed configuration, (b) place or maintain the low flow rate purge gas supply valve in its closed configuration, and (c) place or maintain the purge gas outlet valve in its open configuration when the pressure input data indicates that gas pressure in the chamber has risen above a high pressure threshold level.

10. The substrate processing system according to claim 9, further comprising a high pressure system alarm, wherein the high pressure system alarm is activated when the pressure input data indicates that the gas pressure in the chamber has risen above the high pressure threshold level.

11. The substrate processing system according to claim 1, further comprising: a pressure sensor for sensing gas pressure within the chamber.

12. The substrate processing system according to claim 11, further comprising a low pressure system alarm configured to be activated when gas pressure in the chamber has fallen below a low pressure threshold level.

13. The substrate processing system according to claim 11, further comprising a high pressure system alarm configured to be activated when gas pressure in the chamber has risen above a high pressure threshold level.

14. The substrate processing system according to claim 1, wherein the chamber comprises an extended front end module of the substrate processing system.

15. The substrate processing system according to claim 14, further comprising: a load-lock module operatively coupled with the extended front end module and configured to receive substrates for processing from the extended front end module and to transfer processed substrates into the extended front end module.

16. The substrate processing system according to claim 1, further comprising a substrate handling robotic arm located within the chamber.

17. A substrate processing system, comprising:
a chamber defining an interior volume through which substrates are introduced into the substrate processing system and substrates are removed from the substrate processing system;
a moisture concentration sensor for monitoring moisture concentration in the interior volume of the chamber; and
a control system programmed and configured to: (a) receive moisture concentration input data from the moisture concentration sensor, the moisture concentration input data representing moisture concentration within the chamber, (b) activate a high flow purge gas system at system start up so that purge gas flows through the chamber at a first flow rate, (c) deactivate the high flow purge gas system when the moisture concentration input data indicates that the moisture concentration in the chamber is at or below a first threshold level, and thereafter (d) activate a low flow purge gas system so that purge gas flows through the chamber at a second flow rate that is lower than the first flow rate when the moisture concentration input data indicates that the moisture concentration in the chamber has risen above a second threshold level, and (e) deactivate the low flow purge gas system when the moisture concentration input data indicates that the moisture concentration in the chamber is at or below a third threshold level, wherein the first threshold level, the second threshold level, and the third threshold level are the same as one another or different from one another.

18. The substrate processing system according to claim 17, further comprising: a pressure sensor for sensing gas pressure within the chamber, wherein the pressure sensor sends pressure input data to the control system.

19. The substrate processing system according to claim 18, wherein the control system further is programmed and configured to place and maintain the gas pressure in the chamber within a predetermined pressure range.

20. The substrate processing system according to claim 18, wherein the control system further is programmed and configured to close a purge gas exhaust line when the pressure input data indicates that the gas pressure in the chamber has fallen below a low pressure threshold level.

21. The substrate processing system according to claim 20, wherein the control system further is programmed and adapted to activate a low pressure system alarm when the pressure input data indicates that the gas pressure in the chamber has fallen below the low pressure threshold level.

22. The substrate processing system according to claim 18, wherein the control system further is programmed and configured to: (a) deactivate or maintain a low flow purge gas supply and a high flow purge gas supply in a deactivated condition and (b) open or maintain in an open configuration a purge gas outlet line when the pressure input data indicates that gas pressure in the chamber has risen above a high pressure threshold level.

23. The substrate processing system according to claim 22, wherein the control system further is programmed and adapted to activate a high pressure system alarm when the pressure input data indicates that the gas pressure in the chamber has risen above the high pressure threshold level.

24. The substrate processing system according to claim 18, wherein the chamber comprises an extended front end module of the substrate processing system.

25. The substrate processing system according to claim 24, further comprising: a load-lock module operatively coupled with the extended front end module and configured to receive substrates for processing from the extended front end module and to transfer processed substrates into the extended front end module.

26. The substrate processing system according to claim 18, further comprising a substrate handling robotic arm located within the chamber.

27. A substrate processing method, comprising:
receiving moisture concentration input data representing moisture concentration within a chamber of a substrate processing system;
activating a high flow purge gas system at system start up so that purge gas flows through the chamber at a first flow rate;
deactivating the high flow purge gas system when the moisture concentration in the chamber is at or below a first threshold level;
thereafter activating a low flow purge gas system so that purge gas flows through the chamber at a second flow rate that is lower than the first flow rate when the moisture concentration in the chamber has risen above a second threshold level, wherein the second threshold level is the same as or different from the first threshold level; and
deactivating the low flow purge gas system when the moisture concentration in the chamber is at or below a third threshold level, wherein the third threshold level is the same as or different from the second threshold level.

28. The substrate processing method according to claim 27, further comprising: receiving gas pressure input data representing gas pressure within the chamber.

29. The substrate processing method according to claim 28, further comprising deactivating or maintaining the low flow purge gas system in a closed condition and/or closing a purge gas outlet line when the gas pressure input data indicates that the gas pressure in the chamber has fallen below a low pressure threshold level.

30. The substrate processing method according to claim 29, further comprising activating a low pressure system alarm when the gas pressure in the chamber has fallen below the low pressure threshold level.

31. The substrate processing method according to claim 28, further comprising deactivating or maintaining a low flow purge gas supply in a deactivated condition and opening or maintaining a purge gas outlet line in an open condition when the gas pressure in the chamber is above a high pressure threshold level.

32. The substrate processing method according to claim 31, further comprising activating a high pressure system alarm when the gas pressure in the chamber is above the high pressure threshold level.

33. The substrate processing method according to claim 28, further comprising: placing and maintaining the gas pressure in the chamber within a predetermined pressure range.
